(19) United States
(12) Patent Application Publication
(10) Pub. No.: US 2025/0197674 A1
(43) Pub. Date: Jun. 19, 2025

(54) POLISHING COMPOSITION AND POLISHING METHOD USING THE SAME

(71) Applicant: FUJIMI INCORPORATED, Aichi (JP)

(72) Inventors: Shota SUZUKI, Aichi (JP); Tatsuhiko HIRANO, Aichi (JP); Shogo TSUBOTA, Aichi (JP); Keiji ASHITAKA, Aichi (JP); Masaaki ITO, Aichi (JP)

(21) Appl. No.: 18/847,857

(22) PCT Filed: Mar. 17, 2023
(86) PCT No.: PCT/JP2023/010520

§ 371 Date: Sep. 17, 2024

(30) Foreign Application Priority Data
Mar. 29, 2022 (JP) 2022-053013

(51) Int. Cl. C09G 1/02

(52) U.S. Cl. CPC C09G 1/02

(57) ABSTRACT

The present invention relates to a polishing composition containing abrasive grains and a dispersing medium, in which a pH is less than 5.0, the abrasive grains are surface-modified silica particles in which an organic acid is immobilized on a surface thereof, a surface coverage of silanol groups present on the surface of the surface-modified silica particles is more than 0% and 6.0% or less, and an average primary particle diameter of the abrasive grains is 20 nm or more and 100 nm or less. According to the present invention, there is provided a means capable of improving a polishing removal rate of a silicon oxide film and polishing a silicon oxide film and a silicon nitride film at the substantially same rate.

### TECHNICAL FIELD

The present invention relates to a polishing composition and a polishing method using the same.

### BACKGROUND ART

In recent years, with the multi-layered wiring on a surface of a semiconductor substrate, when a device is produced, a so-called chemical mechanical polishing (CMP) technique for physically polishing and planarizing a semiconductor substrate is used. CMP is a method for planarizing a surface of an object to be polished (polished object) such as a semiconductor substrate or the like by using a polishing composition (slurry) containing abrasive grains of silica, alumina, ceria, or the like, an anticorrosive, a surfactant, and the like, and specifically, is used in processes such as shallow trench isolation (STI), planarization of interlayer dielectric films (ILD films), formation of tungsten plugs, and formation of multilayer interconnections composed of copper and a low dielectric film.

Various studies have been made on a polishing composition (slurry) used for CMP depending on the type of the object to be polished, and the same applies to abrasive grains contained in a polishing composition. For example, JP 2012-40671 A (corresponding to US 2013/0146804 A) proposes, as a polishing composition capable of polishing a silicon nitride film at a high rate, a polishing composition containing colloidal silica in which an organic acid, such as a sulfonic acid, is immobilized, and having a pH in a specific range.

### SUMMARY OF INVENTION

However, with the expansion of applications of CMP, a technique capable of improving the polishing removal rate of not only a silicon nitride film but also a silicon oxide film has been required in gate processing and the like. There is a demand for controlling the polishing removal rates of a silicon oxide film and a silicon nitride film to be almost the same from a demand for simultaneously processing the silicon oxide film and the silicon nitride film.

Therefore, the present invention has been made in view of the above circumstances, and an object thereof is to provide a means capable of improving a polishing removal rate of a silicon oxide film and polishing a silicon oxide film and a silicon nitride film at the substantially same rate.

### Solution to Problem

The present inventors have conducted intensive studies to solve the above problem(s). As a result, the present inventors have found that in a polishing composition having a pH within a specific range, silica particles in which an organic acid is immobilized on a surface thereof are used as abrasive grains, and a surface coverage of silanol groups present on the surface of the silica particles is within a specific range, whereby the above problem can be solved, and have completed the present invention.

That is, the above problem of the present invention can be solved by the following means:
A polishing composition containing abrasive grains and a dispersing medium,
in which pH of the composition is less than 5.0,
the abrasive grains are surface-modified silica particles in which an organic acid is immobilized on a surface thereof,
a surface coverage of silanol groups present on the surface of the surface-modified silica particles is more than 0% and 6.0% or less, and
an average primary particle diameter of the abrasive grains is 20 nm or more and 100 nm or less.

### DESCRIPTION OF EMBODIMENTS

Hereinafter, embodiments of the present invention will be described. The present invention is not limited only to the following embodiments, and various modifications can be made within the scope of claims. The embodiments described in the present specification may be other embodiments by being arbitrarily combined.

Throughout the entire present specification, a singular expression should be understood as encompassing the concept thereof in the plural form, unless specifically noted otherwise. Thus, singular articles (for example, “a”, “an”, “the”, and the like in the case of English) should also be understood as encompassing the concept thereof in the plural form, unless specifically noted otherwise. The terms used in the present specification should be understood as being used in the meaning that is commonly used in the art, unless specifically noted otherwise. Thus, unless defined otherwise, all terminologies and scientific technical terms that are used in the present specification have the same meaning as the general understanding of those skilled in the art to which the present invention pertains. In case of a contradiction, the present specification (including the definitions) takes precedence.

In the present specification, unless otherwise specified, operations and measurements of physical properties and the like are performed under conditions of room temperature (in the range of 20° C. or higher and 25° C. or lower)/relative humidity of 40% RH or more and 50% RH or less.

### <Polishing Composition>

An embodiment of the present invention relates to a polishing composition containing abrasive grains and a dispersing medium, and having pH of less than 5.0, in which the abrasive grains are surface-modified silica particles in which an organic acid is immobilized on a surface thereof, a surface coverage of silanol groups present on the surface of the surface-modified silica particles is more than 0% and 6.0% or less, and an average primary particle diameter of the abrasive grains is 20 nm or more and 100 nm or less. According to the present invention, a polishing removal rate of a silicon oxide film can be improved, and a silicon oxide film and a silicon nitride film can be polished at the substantially same rate.

Although the mechanism by which the above problem can be solved by the polishing composition according to the present invention is not clear in detail, the present inventors presume as follows.

As described above, silica particles as abrasive grains contained in the polishing composition according to the present invention are surface-modified silica particles in which an organic acid is immobilized on a surface, and a surface coverage of silanol groups present on the surface of the surface-modified silica particles (ratio of silanol groups present on the surface of the silica particles substituted by organic acid groups) is more than 0% and 6.0% or less. The abrasive grains are negatively charged by coating with an organic acid in the polishing composition, but it is presumed that the negative charge on the surface of the abrasive grains is small since the coverage is small.

Here, under the condition that pH of the polishing composition is less than 5.0, a surface of a silicon nitride film as an object to be polished is positively charged. Therefore, even when the surface of the abrasive grains is slightly negatively charged, the affinity between the abrasive grains and the silicon nitride film is improved, and a favorable polishing removal rate is obtained for the silicon nitride film.

On the other hand, under the condition that the pH of polishing composition is less than 5.0, a silicon oxide film as an object to be polished has a slightly negatively charged surface, or even when the surface is charged, the charge is almost negligible, and it is considered that an influence on the interaction between the abrasive grains and the silicon oxide film that can be generated by the charge of the abrasive grains is small. For such an object to be polished, in the present invention, it is presumed that dispersibility of the abrasive grains themselves (dispersibility in the polishing composition) can be appropriately adjusted by using the abrasive grains having a surface coverage by the organic acid of more than 0% and 6.0% or less, and as a result, polishing removal rate of the silicon oxide film is also improved.

The silica particles as abrasive grains contained in the polishing composition according to the present invention have an average primary particle diameter of 20 nm or more and 100 nm or less. When the average primary particle diameter is within the range, polishing removal rate of the silicon oxide film can be improved. On the other hand, when the average primary particle diameter is less than 20 nm, a sufficient polishing removal rate of the silicon oxide film cannot be obtained. When the average primary particle diameter is more than 100 nm, aggregation and sedimentation of silica particles occur, so that it becomes difficult to polish the silicon oxide film and the silicon nitride film at the substantially same rate.

According to the polishing composition containing colloidal silica having an organic acid such as sulfonic acid immobilized, as in the technique described in JP 2012-40671 A (corresponding to US 2013/0146804 A), the silicon nitride film can be polished at a high rate. On the other hand, according to the polishing composition of the present invention, since the polishing removal rate of not only the silicon nitride film but also the silicon oxide film can be improved, the silicon oxide film and the silicon nitride film can be polished at the substantially same rate.

The above mechanism is based on speculation, and its correctness does not affect the technical scope of the present invention.

Hereinafter, respective components that can be contained in the polishing composition, the object to be polished and the like will be described.

### [Abrasive Grains]

### (Silica Particles)

Abrasive grains contained in the polishing composition according to the present invention are surface-modified silica particles having an organic acid immobilized on a surface thereof, a surface coverage of silanol groups present on the surface of more than 0% and 6.0% or less, and an average primary particle diameter of 20 nm or more and 100 nm or less. Silica particles (in the present specification, also simply referred to as “surface-modified silica particles” or “abrasive grains according to the present invention”) having such a configuration have an appropriate range of dispersibility in the polishing composition under acidic conditions, particularly when pH is less than 5.0, and thus an effect of improving polishing removal rate of the silicon oxide film is obtained.

In order to more easily obtain the above effect, the surface-modified silica particles are preferably silica particles in which an organic acid is chemically bonded to the surface thereof.

In an embodiment of the present invention, an organic acid to be immobilized on the surface of the silica particles is not particularly limited, and examples thereof include a sulfonic acid, a carboxylic acid, a phosphoric acid, and the like, and a sulfonic acid is preferable. That is, in an embodiment of the present invention, the abrasive grains are preferably sulfonic acid-modified silica particles in which a sulfonic acid group is immobilized on a surface thereof.

In the surface-modified silica particles, an acidic group derived from an organic acid (for example, a sulfonic acid group (sulfo group), a carboxyl group, a phosphoric acid group, and the like; in the present specification, also simply referred to as “organic acid group”) may be directly fixed to the surface by a covalent bond, or may be fixed by a covalent bond via a linker structure. Here, the linker structure means any structure interposed between the surface of the silica particles and the organic acid.

In the surface-modified silica particles, a surface coverage of silanol groups present on the surface (in the present specification, also simply referred to as “surface coverage”) is more than 0% and 6.0% or less. Here, the surface coverage is a value indicating a ratio of an organic acid group which substitutes for a silanol group to the number of silanol groups present on the abrasive grain surface, and is a value obtained by the following Formula (1). Specifically, as the value of the surface coverage, a value obtained by the measurement method and the calculation method described in Examples described later can be adopted. In Examples, a measurement method and a calculation method for sulfonic acid-modified silica particles which are a preferable form will be described, but the measurement method and the calculation method can also be appropriately employed for surface-modified silica particles with other organic acids.

$$\begin{matrix}[ Mathematical Formula 1 ] & \\ Surface coverage ( \% ) = \frac{C \times {N}_{A}}{Mc \times {ρ}_{S} \times A} \times {10}^{- 20} \times 100 & Formula ( 1 )\end{matrix}$$

In the above Formula (1),
C represents concentration of a silane coupling agent used at the time of surface modification (mass concentration with respect to the total mass of raw material silica particles) [% by mass];
N_{A} represents the Avogadro constant (6.022×10²³) [number/mol];
Mc represents molar mass [g/mol] of the silane coupling agent in a completely oxidized state;
ρₛ represents the number of silanol groups per unit area in silica particles in a state where surface modification is not performed (average silanol group density) [number/nm²]; and
A represents a BET specific surface area [m²/g] of silica particles in silica particles in a state where surface modification is not performed.

Here, C and Mc in the above Formula (1) are determined based on concentration and structure of the silane coupling agent used at the time of preparing surface-modified silica particles (at the time of performing “surface modification” described later), respectively. Specifically, C is concentration of the silane coupling agent with respect to the total mass of the raw material silica particles used in the surface modification, and is mass concentration when the total mass of the raw material silica particles is 100% by mass. Mc is a molar mass (molecular weight) calculated from the structure in a state where the silane coupling agent used at the time of surface modification is completely oxidized. When C and Mc are measured for the silica particles after surface modification, C and Mc can be calculated by dissolving the surface of the silica particles under alkaline conditions (alkali treatment) and analyzing the concentration and structure of the desorbed organic acid. Specifically, concentration of the desorbed organic acid with respect to the total mass of the silica particles obtained by the alkali treatment is adopted as C. By specifying the structure of the organic acid desorbed by the alkali treatment by an analysis method such as NMR, the molar mass (molecular weight) calculated from the structure is adopted as Mc.

A calculation method for Mc will be described below by exemplifying sulfonic acid-modified silica particles which are a preferable form of surface-modified silica particles. As described later, examples of a suitable silane coupling agent in preparing sulfonic acid-modified silica particles include an alkoxysilane compound having a thiol group. Here, the “state where the silane coupling agent is completely oxidized” refers to a state where all the alkoxy groups on the silicon atom are hydrolyzed, that is, a state where all the alkoxy groups become hydroxyl groups (—OH), and a state where the thiol groups become sulfonic acid groups (—SO₃H) by being completely oxidized. As a specific example, when 3-mercaptopropyl trimethoxysilane is used as the silane coupling agent, the “state where the silane coupling agent is completely oxidized” is represented by the following chemical formula.

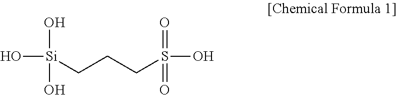 [SMILES: O=S(=O)(O)CCC[Si](O)(O)O]

Therefore, in the case of using 3-mercaptopropyl trimethoxysilane as a silane coupling agent, Mc is 202.26 g/mol.
ρₛ in the above Formula (1) is a value obtained by the following Formula (2), and specifically, a value determined by the measurement method and the calculation method described in Examples described later is adopted.

$$\begin{matrix}[ Mathematical Formula 2 ] & \\ {ρ}_{s} = \frac{c \times a \times {N}_{A}}{m \times {A}^{′}} & Formula ( 2 )\end{matrix}$$

In the above Formula (2),
ρₛ represents the number of silanol groups (average silanol group density) [number/nm²] in silica particles in a state where surface modification is not performed;
c represents concentration [mol/L] of a sodium hydroxide solution used for titration;
a represents volume [L] of the sodium hydroxide solution required to adjust pH from 4.0 to 9.0;
N_{A} represents the Avogadro constant (6.022×10²³) [number/mol];
m represents the total mass (solid content) [g] of silica particles; and
A′ represents a BET specific surface area [nm²/g] of silica particles in silica particles in a state where surface modification is not performed.
ρₛ can be calculated based on each measured value of silica particles when silica particles before being subjected to a treatment (surface modification) for immobilizing an organic acid on the surface are available. When ρₛ is measured for the silica particles after surface modification, ρₛ can be calculated by analyzing the silica particles after an organic acid is desorbed by dissolving the surface of the silica particles under alkaline conditions and removing the organic acid.

As A in the above Formula (1), a value determined by the measurement method described in Examples described later is adopted.

As the value of the surface coverage, first, the number of silanol groups (ρₛ) per unit area and a BET specific surface area (A) of the silica particles are each determined with three or more significant digits by the method described in Examples described later. Concentration (C) of the silane coupling agent used at the time of surface modification and molar mass (Mc) of the silane coupling agent in a completely oxidized state are each determined with three or more significant digits, based on concentration and structure of the silane coupling agent used at the time of preparing the surface-modified silica particles (at the time of performing surface modification). Next, the value of the surface coverage is calculated using these values on the basis of Formula (1). At this time, as the surface coverage (unit: %), a value determined by rounding off the third significant digit (rounding to two significant digits) is adopted. For example, when the value obtained based on Formula (1) is “0.0709%”, the surface coverage is determined as “0.071%” by rounding off the number “9” of the third significant digit.

In the surface-modified silica particles according to the present invention, the surface coverage is more than 0% and 6.0% or less. When the surface coverage is 0%, dispersibility is reduced due to aggregation of the abrasive grains in the polishing composition, and the polishing removal rate of the silicon oxide film decreases. On the other hand, when the surface coverage is more than 6.0%, repulsion between negative charges due to organic acid groups becomes remarkable, dispersibility becomes too high, and the polishing removal rate of the silicon oxide film decreases. In addition, as the negative charge on the surface of the abrasive grains increases, the abrasive grains are easily adsorbed to the positively charged silicon nitride film, and the polishing removal rate of the silicon nitride film increases. As a result, a ratio of the polishing removal rate of the silicon oxide film to the polishing removal rate of the silicon nitride film (hereinafter, also referred to as “polishing removal rate ratio of SiO₂/SiN”) tends to be small (tends to be less than 1.0). That is, it is difficult to polish the silicon oxide film and the silicon nitride film at the same rate.

The surface coverage is preferably 0.050% or more, more preferably 0.10% or more, further preferably 0.50% or more, still more preferably 0.70% or more, still more preferably 0.80% or more, particularly preferably 1.0% or more, and most preferably 1.5% or more. When the abrasive grains have the above-described surface coverage, the polishing removal rate of the silicon oxide film can be further improved.

The surface coverage is preferably 5.0% or less, more preferably 4.0% or less, further preferably less than 3.6%, still more preferably less than 2.9%, still more preferably 2.5% or less, particularly preferably 2.3% or less, and most preferably 2.0% or less. When the abrasive grains have the above-described surface coverage, the polishing removal rate of the silicon oxide film can be further improved. The polishing removal rate ratio of SiO₂/SiN becomes 1.0 or more, and the effect of polishing the silicon oxide film and the silicon nitride film at the same rate can be more easily obtained.

The surface coverage is preferably 0.050% or more and 5.0% or less, more preferably 0.10% or more and 4.0% or less, further preferably 0.50% or more and less than 3.6%, still more preferably 0.70% or more and less than 2.9%, still more preferably 0.80% or more and 2.5% or less, particularly preferably 1.0% or more and 2.3% or less, and most preferably 1.5% or more and 2.0% or less. When the abrasive grains have the above-described surface coverage, the polishing removal rate ratio of SiO₂/SiN becomes 1.0 or more, and the polishing removal rate ratio can be set to about 1.2 or more and 1.4 or less, which is preferable.

The reason why the polishing removal rate ratio of SiO₂/SiN is preferably about 1.2 or more and 1.4 or less is that the polishing removal rate ratio is in a range suitable for finish processing and gate processing. For example, in gate processing, a polycrystalline silicon (polysilicon) layer-silicon nitride layer-silicon oxide layer is formed on a silicon wafer from below, and then a silicon nitride layer and a silicon oxide layer are polished to expose the polysilicon layer. When the polishing removal rate ratio of SiO₂/SiN is 1.0 or more and 2.3 or less, both the silicon nitride layer and the silicon oxide layer can be processed simultaneously, but in order not only to expose the polysilicon layer by polishing the silicon oxide layer formed over the entire surface on the silicon wafer, but also to completely remove the silicon oxide film of a target portion, it is preferable that the conditions be such that the silicon oxide layer is more easily polished with respect to the silicon nitride layer. Therefore, the polishing removal rate ratio of SiO₂/SiN is more preferably more than 1.0 and more preferably about 1.2 or more and 1.4 or less.

Therefore, the polishing composition is preferably designed so that the polishing removal rate ratio of the polishing removal rate of the silicon oxide film/the silicon nitride film (SiO₂/SiN) is 1.0 or more and 2.3 or less. At this time, the polishing removal rate ratio of SiO₂/SiN is preferably 1.1 or more and 1.5 or less, more preferably 1.2 or more and 1.4 or less, and particularly preferably 1.3.

A method for introducing the organic acid into the surface of the silica particles is not particularly limited, and examples thereof include a method in which a thiol group, an alkyl group, a hydroxyl group, an aldehyde group, or the like is first introduced into the surface of the silica particles, and then oxidized into an organic acid group such as a sulfonic acid group or a carboxylic acid group, and a method in which an organic acid group in a state where a protecting group is bonded is introduced into the surface of the silica particles, and then the protecting group is eliminated.

As a specific example, when sulfonic acid group is immobilized on silica particles, it is possible to perform the immobilization, for example, by the method described in “Sulfonic acid-functionalized silica through of thiol groups”, Chem. Commun. 246-247 (2003). Specifically, it is possible to obtain silica particles having a sulfonic acid group immobilized on the surface by performing surface modification of coupling a silane coupling agent having a thiol group such as 3-mercaptopropyl trimethoxysilane to silica particles and then oxidizing the thiol group with an oxidizing agent such as hydrogen peroxide.

Alternatively, when the carboxylic acid group is immobilized on silica particles, it is possible to perform the immobilization, for example, by the method described in “Novel Silane Coupling Agents Containing a Photolabile 2-Nitrobenzyl Ester for Introduction of a Carboxy Group on the Surface of Silica Gel”, Chemistry Letters, 3, 228-229 (2000). Specifically, it is possible to obtain silica particles having a carboxylic acid group immobilized on the surface by performing surface modification of coupling a silane coupling agent containing a photoreactive 2-nitrobenzyl ester to silica particles and then irradiating with light.

As described above, surface modification in which a silane coupling agent having a functional group capable of being chemically converted into an organic acid group is added to silica particles, and then the functional group is converted into an organic acid group is performed, whereby silica particles having an organic acid group immobilized on the surface thereof can be obtained. At this time, the surface coverage can be controlled by adjusting the addition amount of the silane coupling agent.

For example, when sulfonic acid-modified silica particles having a sulfonic acid group immobilized, which are a preferred form, are prepared, the lower limit of the concentration (C in the above Formula (1)) of the silane coupling agent (silane coupling agent having a thiol group) with respect to the total mass (total mass of solid content) of raw material silica particles is preferably 0.00500% by mass or more, more preferably 0.0500% by mass or more, further preferably 0.100% by mass or more, particularly preferably more than 0.100% by mass, and most preferably 0.150% by mass or more.

The upper limit of C in the above Formula (1) is preferably less than 1.00% by mass, more preferably 0.500% by mass or less, further preferably less than 0.500% by mass, particularly preferably less than 0.400% by mass, and most preferably 0.300% by mass or less.

C in the above Formula (1) is preferably 0.00500% by mass or more and less than 1.00% by mass, more preferably 0.0500% by mass or more and 0.500% by mass or less, further preferably 0.100% by mass or more and less than 0.500% by mass, particularly preferably more than 0.100% by mass and less than 0.400% by mass, and most preferably 0.150% by mass or more and 0.300% by mass or less.

The silane coupling agent having a thiol group is not particularly limited, and examples thereof include alkoxysilane compounds having a thiol group such as 3-mercaptopropyl trimethoxysilane, 3-mercaptopropyl dimethoxymethylsilane, 3-mercaptopropyl methoxydimethylsilane, 2-mercaptopropyl triethoxysilane, 2-mercaptoethyl trimethoxysilane, and 2-mercaptoethyl triethoxysilane. Among them, 3-mercaptopropyl trimethoxysilane is preferable. The silane coupling agent is not limited to the monomer (single molecule) as described above, and may be an oligomer of a dimer or more. After preparing an oligomer such as a dimer or more in advance using a monomer, the oligomer may be used as a silane coupling agent.

A method of oxidizing a thiol group is not particularly limited, and a known method can be used. The type of the oxidizing agent to be used and the addition amount thereof are also not particularly limited, and those skilled in the art can appropriately select the oxidizing agent.

In an embodiment of the present invention, the silica particles (raw material of the surface-modified silica particles) are not particularly limited, but from the viewpoint of dispersibility and defect performance, fumed silica or colloidal silica is preferable, and colloidal silica is more preferable. Examples of the method for producing colloidal silica include a sodium silicate method and a sol-gel method, and any colloidal silica produced by any production method is suitably used. However, from the viewpoint of reducing metal impurities, colloidal silica produced by a sol-gel method is preferable. Colloidal silica produced by a sol-gel method is preferable because it has a small content of metal impurities having a property of diffusing in a semiconductor and corrosive ions such as chloride ions.

The silica particles may be used singly or in combination of two or more kinds thereof.

In an embodiment of the present invention, an average primary particle diameter of the abrasive grains (average primary particle diameter in a state where an organic acid is immobilized; the same applies hereinafter) is 20 nm or more and 100 nm or less. The average primary particle diameter of the abrasive grains is preferably 21 nm or more, more preferably 22 nm or more, and particularly preferably 23 nm or more. The average primary particle diameter of the abrasive grains is preferably 90 nm or less, more preferably 80 nm or less, further preferably 70 nm or less, particularly preferably 50 nm or less, and most preferably 30 nm or less. The average primary particle diameter of the abrasive grains is preferably 21 nm or more and 90 nm or less, more preferably 21 nm or more and 80 nm or less, further preferably 22 nm or more and 70 nm or less, particularly preferably 23 nm or more and 50 nm or less, and most preferably 23 nm or more and 30 nm or less. When the abrasive grains have the above-described average primary particle diameter, the polishing removal rate of the silicon oxide film is further improved, and the polishing removal rate ratio of SiO₂/SiN can be set to about 1.2 or more and 1.4 or less, which is preferable.

In an embodiment of the present invention, an average secondary particle diameter of the abrasive grains (average secondary particle diameter in a state where an organic acid is immobilized; the same applies hereinafter) is preferably 35 nm or more, more preferably 38 nm or more, further preferably 40 nm or more, and particularly preferably more than 40 nm. The average secondary particle diameter of the abrasive grains is preferably 250 nm or less, more preferably 200 nm or less, further preferably 150 nm or less, particularly preferably 100 nm or less, and most preferably 50 nm or less. The average secondary particle diameter of the abrasive grains is preferably 35 nm or more and 250 nm or less, more preferably 38 nm or more and 200 nm or less, further preferably 40 nm or more and 150 nm or less, particularly preferably more than 40 nm and 100 nm or less, and most preferably more than 40 nm and 50 nm or less. When the abrasive grains have the above-described average secondary particle diameter, the polishing removal rate of the silicon oxide film is further improved, and the polishing removal rate ratio of SiO₂/SiN can be set to about 1.2 or more and 1.4 or less, which is preferable.

The average primary particle diameter of the abrasive grains can be calculated from a specific surface area of the abrasive grains by BET method and a density of the abrasive grains, and specifically, a value obtained by the measurement method described in Examples described later is adopted. The average secondary particle diameter of the abrasive grains can be calculated by a dynamic light scattering method represented by a laser diffraction scattering method, and specifically, a value obtained by the measurement method described in Examples described later is adopted.

In the surface-modified silica particles according to the present invention, the number of silanol groups (ρₛ: the number of silanol groups per unit area in silica particles in a state where surface modification is not performed) in the above Formula (1) is preferably 2.50/nm² or more and 10.0/nm² or less, more preferably 3.00/nm² or more and 8.00/nm² or less, further preferably 3.20/nm² or more and 7.00/nm² or less, particularly preferably 3.50/nm² or more and 6.00/nm² or less, and most preferably 3.60/nm² or more and 5.00/nm² or less. When the silica particles before surface modification have the number of silanol groups (ρₛ) described above, the polishing removal rate of the silicon oxide film is further improved, and the polishing removal rate ratio of SiO₂/SiN can be set to about 1.2 or more and 1.4 or less, which is preferable.

A concentration (content) of the surface-modified silica particles as abrasive grains in the polishing composition according to the present invention is not particularly limited. In the case of a polishing composition that is directly used as a polishing liquid for polishing an object to be polished (typically a slurry polishing liquid, sometimes referred to as a working slurry or a polishing slurry), a concentration (content) of the abrasive grains is preferably 0.5% by mass or more, more preferably 1% by mass or more, further preferably more than 1% by mass, particularly preferably 2% by mass or more, and most preferably 3% by mass or more, with respect to the total mass of the polishing composition. As the concentration of the abrasive grains increases, the polishing removal rate can be further improved.

The concentration (content) of the abrasive grains is preferably 20% by mass or less, more preferably 15% by mass or less, further preferably 10% by mass or less, and particularly preferably 5% by mass or less, with respect to the total mass of the polishing composition. Within the above range, the generation of defects such as residual abrasive grains can be further reduced.

As a preferred example of the concentration (content) of the abrasive grains, the concentration (content) thereof is preferably 0.5% by mass or more and 20% by mass or less, more preferably 1% by mass or more and 15% by mass or less, further preferably more than 1% by mass and 10% by mass or less, particularly preferably 2% by mass or more and 10% by mass or less, and most preferably 3% by mass or more and 5% by mass or less, with respect to the total mass of the polishing composition. When the concentration (content) of the abrasive grains is in the above range, not only the polishing removal rate of the silicon oxide film can be further improved, but also the residual abrasive grains on a surface of an object to be polished after polishing can be reduced. In the case of using two or more kinds of abrasive grains, the concentration (content) of the abrasive grains means the total amount of all the abrasive grains.

In the case of a polishing composition that is diluted and used for polishing (that is, a concentrated solution), a content of the abrasive grains is usually appropriately 25% by mass or less and more preferably 20% by mass or less, from the viewpoint of storage stability, filterability, and the like. From the viewpoint of taking advantage of a concentrated solution, the content of the abrasive grains is preferably 3% by mass or more and more preferably 5% by mass or more.

In an embodiment of the present invention, the abrasive grains may include abrasive grains (in the present specification, also referred to as “other abrasive grains”) other than the surface-modified silica particles. The type of other abrasive grains that can be contained in the polishing composition is not particularly limited, and examples thereof include oxides such as silica other than the surface-modified silica particles, alumina, zirconia, and titania. The other abrasive grains can be used singly or in combination of two or more kinds thereof. As the other abrasive grains, a commercially available product or a synthetic product may be used. However, in order to more easily obtain the effect(s) of the present invention, it is preferable that the ratio of other abrasive grains contained in the polishing composition is small, and it is more preferable that the polishing composition does not substantially contain abrasive grains other than the surface-modified silica particles. Here, “not substantially contain” includes a case where other abrasive grains are contained in the polishing composition at a ratio of 0.1% by mass or less, preferably 0.01% by mass or less (lower limit: 0% by mass) in addition to a case where other abrasive grains are not contained at all in the polishing composition.

### [Dispersing Medium]

The polishing composition according to the present invention contains a dispersing medium. The dispersing medium disperses or dissolves each component.

The dispersing medium preferably contains water. A content of water in the dispersing medium is not particularly limited, and is preferably 50% by mass or more, and more preferably 90% by mass or more, with respect to the total mass of the dispersing medium, and further preferably only water. From the viewpoint of preventing an influence of impurities on other components of the polishing composition, it is preferable to use water having as high purity as possible. Purity of water can be increased by, for example, operations such as removal of impurity ions using an ion exchange resin, removal of foreign substances by a filter, and distillation. Specifically, as water, for example, deionized water (ion-exchanged water), pure water, ultrapure water, or distilled water is preferable, and deionized water (ion-exchanged water) is more preferable. An organic solvent or the like may be further contained as the dispersing medium for the purpose of controlling the dispersibility or the like of other components of the polishing composition. In this case, examples of an organic solvent to be used include acetone, acetonitrile, ethanol, methanol, isopropanol, glycerin, ethylene glycol, propylene glycol, triethanolamine, which are organic solvents miscible with water, and the like. These organic solvents may be used for dispersing or dissolving each component without being mixed with water, and then mixed with water. These organic solvents can be used singly or in combination of two or more kinds thereof.

### [pH Adjusting Agent]

The polishing composition according to an embodiment of the present invention preferably further contains a pH adjusting agent. The pH adjusting agent can contribute to the adjustment of pH of the polishing composition by selecting the type and the addition amount thereof.

The pH adjusting agent is not particularly limited as long as it is a compound having a pH adjusting function, and a known compound can be used. The pH adjusting agent is not particularly limited as long as it has a pH adjusting function, and examples thereof include an acid, an alkali, and the like.

As the acid, either an organic acid or an inorganic acid may be used. The organic acid is not particularly limited, and examples thereof include carboxylic acids such as formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, and lactic acid, sulfonic acids such as methanesulfonic acid, ethanesulfonic acid, isethionic acid, sulfanilic acid (4-aminobenzenesulfonic acid), benzenesulfonic acid, camphorosulfonic acid (10-camphorosulfonic acid), 2-hydroxyethanesulfonic acid, morpholinopropanesulfonic acid, m-xylene-4-sulfonic acid, and naphthalenesulfonic acid, and the like. The inorganic acid is not particularly limited, and examples thereof include sulfuric acid, nitric acid, boric acid, carbonic acid, hypophosphorous acid, phosphorous acid, phosphoric acid, and the like.

Among the acids used as the pH adjusting agent, organic acids are preferable, and malic acid, citric acid, and maleic acid are more preferable. When an inorganic acid is used, nitric acid, sulfuric acid, or phosphoric acid is preferable.

The alkali is not particularly limited, and examples thereof include a hydroxide of an alkali metal such as potassium hydroxide; ammonia and quaternary ammonium salts such as tetramethylammonium and tetraethylammonium; amines such as ethylenediamine and piperazine, and the like. Among them, potassium hydroxide and ammonia are preferable.

The pH adjusting agent may be used singly or in combination of two or more kinds thereof.

A content of the pH adjusting agent is not particularly limited, and is preferably an amount that can be set pH value of the polishing composition to a value within a preferable range described later.

### [Ammonium Salt]

The polishing composition according to an embodiment of the present invention preferably further contains an ammonium salt. By using an ammonium salt, the polishing removal rate of the silicon oxide film can be further improved. As described above, it is presumed that the surface of the silicon oxide film and the surface of the abrasive grains coated with the organic acid are slightly negatively charged under the condition that pH of the polishing composition is less than 5.0. By adding an ammonium salt (ammonium ion), the electrical conductivity of the polishing composition can be improved, and an electric double layer on the surface of the silicon oxide film and the surface of the abrasive grains can be shrunk. As described above, the electric double layer shrinks, so that repulsion between the surface of the silicon oxide film and the surface of the abrasive grains is alleviated, and the abrasive grains can be easily brought close to the surface of the silicon oxide film, and thus it is presumed that the above effect(s) can be obtained.

The ammonium salt may be any salt that produces ammonium ions by ionization, and either an inorganic acid salt (inorganic ammonium salt) or an organic acid salt (organic ammonium salt) may be used. Examples of the inorganic acid salt include ammonium sulfate, ammonium nitrate, ammonium chloride, ammonium fluoride, ammonium borate, ammonium carbonate, diammonium hydrogen carbonate, ammonium dihydrogen carbonate, ammonium hypophosphite, ammonium phosphite, ammonium phosphate, and the like. Examples of the organic acid salt include ammonium formate, ammonium acetate, ammonium propionate, ammonium butyrate, ammonium valerate, ammonium benzoate, ammonium glycolate, ammonium salicylate, ammonium glycerate, ammonium oxalate, ammonium malonate, ammonium succinate, ammonium glutarate, ammonium adipate, ammonium pimelate, ammonium maleate, ammonium phthalate, ammonium malate, ammonium tartrate, diammonium hydrogen citrate, triammonium citrate, ammonium lactate, ammonium diglycolate, and the like.

Among them, inorganic acid salts (inorganic ammonium salts) are preferable, and ammonium sulfate and ammonium nitrate are more preferable. When an organic acid salt (organic ammonium salt) is used, diammonium hydrogen citrate and triammonium citrate are more preferable. By using these inorganic acid salts or organic acid salts, the polishing removal rate of the silicon oxide film can be further improved. That is, in a preferred embodiment, the polishing composition according to the present invention further contains at least one selected from the group consisting of ammonium sulfate, ammonium nitrate, diammonium hydrogen citrate, and triammonium citrate. In a preferred embodiment, the polishing composition according to the present invention contains ammonium sulfate or ammonium nitrate. In a preferred embodiment, the polishing composition according to the present invention contains ammonium sulfate.

The ammonium salt may be used singly or in combination of two or more kinds thereof.

A concentration (content) of the ammonium salt in the polishing composition according to the present invention is not particularly limited, and can be appropriately selected according to the electrical conductivity. In the case of a polishing composition that is directly used as a polishing liquid for polishing an object to be polished (typically a slurry polishing liquid, sometimes referred to as a working slurry or a polishing slurry), a concentration (content) of the ammonium salt in the polishing composition is preferably 5 mM or more, more preferably 10 mM or more, and particularly preferably 20 mM or more. The concentration (content) of the ammonium salt in the polishing composition is preferably 100 mM or less, more preferably 60 mM or less, and particularly preferably 50 mM or less.

As a preferred example of the concentration (content) of the ammonium salt, the concentration (content) thereof in the polishing composition is preferably 5 mM or more and 100 mM or less, more preferably 10 mM or more and 60 mM or less, and particularly preferably 20 mM or more and 50 mM or less. When the concentration (content) of the ammonium salt is in the above range, not only the polishing removal rate of the silicon oxide film can be further improved, but also the effect of polishing the silicon oxide film and the silicon nitride film at the same rate is more easily obtained. In the case of using two or more kinds of ammonium salts, the concentration (content) of the ammonium salt means the total amount of all the ammonium salts.

In the case of a polishing composition that is diluted and used for polishing (that is, a concentrated solution), a concentration (content) of the ammonium salt is usually appropriately 200 mM or less and more preferably 150 mM or less. From the viewpoint of taking advantage of a concentrated solution, the content of the abrasive grains is preferably 30 mM or more and more preferably 50 mM or more.

### [Other Components]

The polishing composition according to the present invention may further contain known components such as abrasive grains other than the ones described above, a chelating agent, a thickener, an oxidizing agent, a dispersing agent, a surface protecting agent, a wetting agent, a surfactant, an anticorrosive (rust inhibitor), an antifungal agent (antiseptic agent), and a water-soluble polymer, within a range not impairing the effect(s) of the present invention. A content of the other components may be appropriately set depending on the purpose of addition.

From the viewpoint of obtaining a polishing composition suitable for finish processing and gate processing, the polishing composition preferably further contains a water-soluble polymer. As described above, for example, in gate processing, a polycrystalline silicon (polysilicon) layer-silicon nitride layer-silicon oxide layer is formed, and then polishing is performed to expose the polysilicon layer. At this time, when the polishing composition contains a water-soluble polymer, the water-soluble polymer is adsorbed on the surface of the polysilicon layer, and the surface of the polysilicon layer is protected from a mechanical action by abrasive grains, so that an effect of suppressing excessive polishing of the polysilicon layer can be obtained. Hereinafter, the water-soluble polymer will be described.

### (Water-Soluble Polymer)

Examples of the water-soluble polymer include naturally-derived polymers such as guar gum, locust bean gum, quince seed, carrageenan, galactan, gum arabic, gum tragacanth, pectin, mannan, xanthan gum, dextran, succinoglucan, curdlan, hyaluronic acid, gelatin, casein, albumin, collagen, dextrin, pullulan, lignin, and lignin sulfonic acid; and synthetic polymers such as poly(meth)acrylic acid, polyvinyl methyl ether, polyacrylamide, acrylic acid/acrylic acid ester copolymer, polyvinyl alcohol, hydroxyethyl cellulose, hydroxypropyl cellulose, hydroxyethyl methyl cellulose, hydroxypropyl methyl cellulose, ethyl cellulose, ethyl hydroxyethyl cellulose, carboxymethyl cellulose, polyvinyl imidazole, polyvinyl carbazole, polyvinyl pyrrolidone, poly N-vinylformamide, poly N-vinylacetamide, polyvinyl caprolactam, polyvinyl piperidine, polyaniline sulfonic acid, vinyl alcohol-vinyl pyrrolidone copolymer, vinyl alcohol-ethylene copolymer, and a polyoxyalkylene group-containing compound.

In the present specification, the term “(meth)acryl” includes both acryl and methacryl.

From the viewpoint of further improving the above effect, the water-soluble polymer is preferably a polyoxyalkylene group-containing compound. Here, the “polyoxyalkylene group-containing compound” is an organic compound containing a polyoxyalkylene group. The “polyoxyalkylene group-containing compound” may be a compound in which a part of a functional group of a compound having a polyoxyalkylene group is substituted or polymerized. These may be used singly or in combination of two or more kinds thereof.

Specific examples of the polyoxyalkylene group include a polyoxyethylene group, a polyoxypropylene group, a polyoxytetramethylene group, a polyoxyalkylene group in which an oxyethylene group and an oxypropylene group are block or random bonded to each other, a group in which a polyoxybutylene group is further contained in addition to the polyoxyethylene group, polyoxypropylene group, or polyoxyalkylene group by a block or a random bond, and the like.

Among them, the polyoxyalkylene group-containing compound is preferably one or more selected from the group consisting of polyethylene glycol, polypropylene glycol, polytetrahydrofuran (polyoxytetramethylene glycol), and polybutylene glycol, and more preferably polyethylene glycol.

A weight average molecular weight (Mw) of the polyoxyalkylene group-containing compound is not particularly limited, and is preferably 100 or more, more preferably 150 or more, and further preferably 200 or more. The upper limit thereof is preferably 30,000 or less, more preferably 10,000 or less, and further preferably 1,000 or less. That is, the weight average molecular weight (Mw) of the polyoxyalkylene group-containing compound is preferably 100 or more and 30,000 or less, more preferably 150 or more and 10,000 or less, and further preferably 200 or more and 1,000 or less.

In the present specification, a weight average molecular weight (Mw) of polyoxyalkylene group-containing compound can be measured by gel permeation chromatography (GPC) using polyethylene glycol as a standard substance.

### (Antifungal Agent)

When the polishing composition according to the present invention contains the water-soluble polymer, the polishing composition preferably further contains an antifungal agent (antiseptic agent). The antifungal agent (antiseptic agent) that can be used when the polishing composition according to the present invention contains the antifungal agent (antiseptic agent) is not particularly limited, and can be appropriately selected according to the type of water-soluble polymer. Specific examples thereof include isothiazoline-based antiseptic agents such as 2-methyl-4-isothiazoline-3-one, 5-chloro-2-methyl-4-isothiazoline-3-one, and 1,2-benzoisothiazol-3(2H)-one (BIT); paraoxybenzoic acid esters (parahydroxybenzoic acid esters) such as methyl paraoxybenzoate (methyl parahydroxybenzonate), ethyl paraoxybenzoate (ethyl parahydroxybenzoate), butyl paraoxybenzoate (butyl parahydroxybenzoate), and benzyl paraoxybenzoate (benzyl parahydroxybenzoate); salicylic acid, methyl salicylate, phenol, catechol, resorcinol, hydroquinone, isopropylphenol, cresol, thymol, phenoxyethanol, phenylphenol (2-phenylphenol, 3-phenylphenol, and 4-phenylphenol), 2-phenylethyl alcohol (phenethyl alcohol); and the like.

In an embodiment of the present invention, the polishing composition is substantially composed of the abrasive grains according to the present invention, an ammonium salt, a pH adjusting agent, a water-soluble polymer, water, and at least one of an antifungal agent and an organic solvent. In an embodiment of the present invention, the polishing composition is substantially composed of the abrasive grains according to the present invention, an ammonium salt, a pH adjusting agent, water, and an organic solvent. In an embodiment of the present invention, the polishing composition is substantially composed of the abrasive grains according to the present invention, an ammonium salt, a pH adjusting agent, and water. In an embodiment of the present invention, the polishing composition is substantially composed of the abrasive grains according to the present invention, a pH adjusting agent, and water. In an embodiment of the present invention, the polishing composition is substantially composed of the abrasive grains according to the present invention, an ammonium salt, a pH adjusting agent, a water-soluble polymer, water, and an antifungal agent.

In the embodiment, “the polishing composition is substantially composed of X” means that the total content of X exceeds 99% by mass (upper limit: 100% by mass) with respect to 100% by mass of the total mass of the polishing composition (with respect to the polishing composition). Preferably, the polishing composition is composed of X (the total content=100% by mass). For example, “the polishing composition is substantially composed of the abrasive grains according to the present invention, an ammonium salt, a pH adjusting agent, a water-soluble polymer, a dispersing medium (preferably, water), and at least one of an antifungal agent and an organic solvent” means that the total content of the abrasive grains according to the present invention, an ammonium salt, a pH adjusting agent, a water-soluble polymer, a dispersing medium (preferably, water), an antifungal agent, and an organic solvent exceeds 99% by mass (upper limit: 100% by mass) with respect to 100% by mass of the total mass of the polishing composition (with respect to the polishing composition), and the polishing composition is preferably composed of the abrasive grains according to the present invention, an ammonium salt, a pH adjusting agent, a water-soluble polymer, a dispersing medium (preferably, water), and at least one of an antifungal agent and an organic solvent (the total content=100% by mass). As another embodiment, “the polishing composition is substantially composed of the abrasive grains according to the present invention, an ammonium salt, a pH adjusting agent, a dispersing medium (preferably, water), and an organic solvent” means that the total content of the abrasive grains according to the present invention, an ammonium salt, a pH adjusting agent, a dispersing medium (preferably, water), and an organic solvent exceeds 99% by mass (upper limit: 100% by mass) with respect to 100% by mass of the total mass of the polishing composition (with respect to the polishing composition), and the polishing composition is preferably composed of the abrasive grains according to the present invention, an ammonium salt, a pH adjusting agent, a dispersing medium (preferably, water), and an organic solvent (the total content=100% by mass). As another embodiment, “the polishing composition is substantially composed of the abrasive grains according to the present invention, an ammonium salt, a pH adjusting agent, and a dispersing medium (preferably, water)” means that the total content of the abrasive grains according to the present invention, an ammonium salt, a pH adjusting agent, and a dispersing medium (preferably, water) exceeds 99% by mass (upper limit: 100% by mass) with respect to 100% by mass of the total mass of the polishing composition (with respect to the polishing composition), and the polishing composition is preferably composed of the abrasive grains according to the present invention, an ammonium salt, a pH adjusting agent, and a dispersing medium (preferably, water) (the total content=100% by mass). As another embodiment, “the polishing composition is substantially composed of the abrasive grains according to the present invention, a pH adjusting agent, and a dispersing medium (preferably, water)” means that the total content of the abrasive grains according to the present invention, a pH adjusting agent, and water exceeds 99% by mass (upper limit: 100% by mass) with respect to 100% by mass of the total mass of the polishing composition (with respect to the polishing composition), and the polishing composition is preferably composed of the abrasive grains according to the present invention, a pH adjusting agent, and a dispersing medium (preferably, water) (the total content=100% by mass). As another embodiment, “the polishing composition is substantially composed of the abrasive grains according to the present invention, an ammonium salt, a pH adjusting agent, a water-soluble polymer, water, and an antifungal agent” means that the total content of the abrasive grains according to the present invention, an ammonium salt, a pH adjusting agent, a water-soluble polymer, water, and an antifungal agent exceeds 99% by mass (upper limit: 100% by mass) with respect to 100% by mass of the total mass of the polishing composition (with respect to the polishing composition), and the polishing composition is preferably composed of the abrasive grains according to the present invention, an ammonium salt, a pH adjusting agent, a water-soluble polymer, water, and an antifungal agent (the total content=100% by mass).

[pH]

pH of the polishing composition according to an embodiment of the present invention is less than 5.0. When pH is 5.0 or more, the polishing removal rate of the silicon oxide film decreases. When pH value further increases (for example, 6.0 or more), the silicon oxide film and the silicon nitride film cannot be polished at the same rate because the polishing removal rate ratio of SiO₂/SiN becomes excessive, for example.

The upper limit of pH of the polishing composition may be less than 5.0, but is preferably 4.5 or less, more preferably 4.0 or less, further preferably less than 4.0, particularly preferably 3.5 or less, and most preferably 3.2 or less. When pH of the polishing composition has the above upper limit, the polishing removal rate of the silicon oxide film can be further improved. The effect of polishing the silicon oxide film and the silicon nitride film at the same rate can be more easily obtained.

The lower limit of pH of the polishing composition is not particularly limited, but is preferably 1.0 or more, more preferably 1.3 or more, more preferably 1.5 or more, further preferably 2.0 or more, particularly preferably 2.3 or more, and most preferably 2.5 or more. When pH of the polishing composition has the above lower limit, the polishing removal rate of the silicon oxide film can be further improved.

pH of the polishing composition is preferably 1.0 or more and 4.5 or less, more preferably 1.3 or more and 4.0 or less, further preferably 1.5 or more and less than 4.0, further preferably 2.0 or more and 3.5 or less, particularly preferably 2.3 or more and 3.2 or less, and most preferably 2.5 or more and 3.2 or less. When pH of the polishing composition is within the above range, the polishing removal rate of the silicon oxide film can be further improved. The polishing removal rate ratio of SiO₂/SiN can be set to 1.0 or more, and further about 1.2 or more and 1.4 or less, which is preferable. pH value of the polishing composition is measured by a pH meter (Model No.: LAQUA (registered trademark) manufactured by HORIBA, Ltd.) under the condition of a liquid temperature of 25° C.

### [Electrical Conductivity]

An electrical conductivity (EC) of the polishing composition according to an embodiment of the present invention is not particularly limited. For example, the lower limit value of the electrical conductivity is preferably 0.5 mS/cm or more, more preferably 1.0 mS/cm or more, further preferably 5.0 mS/cm or more, and particularly preferably 8.3 mS/cm or more. When the electrical conductivity of the polishing composition has the above lower limit, the polishing removal rate of the silicon oxide film can be further improved.

The upper limit value of the electrical conductivity is, for example, preferably 25 mS/cm or less, more preferably 20 mS/cm or less, further preferably 15 mS/cm or less, and particularly preferably 10 mS/cm or less. When the electrical conductivity of the polishing composition has the above upper limit, the polishing removal rate of the silicon oxide film can be further improved while maintaining favorable dispersion stability of the abrasive grains. A preferred range of the electrical conductivity is preferably 0.5 mS/cm or more and 25 mS/cm or less, more preferably 1.0 mS/cm or more and 20 mS/cm or less, further preferably 5.0 mS/cm or more and 15 mS/cm or less, and particularly preferably 8.3 mS/cm or more and 10 mS/cm or less. The electrical conductivity of the polishing composition can be measured by a tabletop-type electrical conductivity meter (Model No.: DS-71 manufactured by HORIBA, Ltd.).

The electrical conductivity can be controlled by adjusting pH of the polishing composition, the type and addition amount of pH adjusting agent to be optionally added, the type and addition amount of an ammonium salt to be optionally added, and the like.

### <Method for Producing Polishing Composition>

A method for producing a polishing composition (preparation method) according to the present invention is not particularly limited, and for example, a production method including preparing silica particles having the specific surface coverage and the specific average primary particle diameter described above, and stirring and mixing the silica particles with a dispersing medium (preferably, water) and an ammonium salt and/or other components (for example, a pH adjusting agent or the like) as necessary can be appropriately adopted. That is, another aspect of the present invention relates to a method for producing a polishing composition, the production method including selecting, as abrasive grains, surface-modified silica particles having a surface coverage of silanol groups present on a surface thereof of more than 0% and 6.0% or less and an average primary particle diameter of 20 nm or more and 100 nm or less, and mixing the silica particles with a dispersing medium. In this aspect, it is preferable to further include mixing an ammonium salt. In this aspect, it is preferable to further include mixing a pH adjusting agent. The silica particles, the dispersing medium, the ammonium salt, and other components (for example, a pH adjusting agent or the like) are the same as those described in the section of <Polishing composition>, and thus the description thereof is omitted here.

In an embodiment of the present invention, the surface-modified silica particles having a surface coverage of silanol groups present on the surface thereof of more than 0% and 6.0% or less can be prepared by introducing an organic acid into a surface of silica particles by the method described in the section of [Abrasive grains].

The silica particles as abrasive grains can be stirred and mixed with a dispersing medium (preferably water) and an ammonium salt and/or other components as necessary to produce a polishing composition. At this time, mixing order of the respective components is not particularly limited. For example, when a polishing composition contains silica particles, a dispersing medium, and an ammonium salt, the polishing composition can be prepared by: feeding silica particles, a dispersing medium, and an ammonium salt collectively, and optionally adding a pH adjusting agent thereto so as to obtain a desired pH; feeding silica particles and an ammonium salt into a dispersing medium, and optionally adding a pH adjusting agent thereto so as to obtain a desired pH; feeding silica particles and an ammonium salt into a dispersing medium in this order, and optionally adding a pH adjusting agent thereto so as to obtain a desired pH; feeding an ammonium salt and silica particles into a dispersing medium in this order, and optionally adding a pH adjusting agent thereto so as to obtain a desired pH; or the like. Temperature at which respective components are stirred and mixed is not particularly limited, and is preferably 10° C. or higher and 40° C. or lower, and heating may be performed in order to increase rate of dissolution. Mixing time is also not particularly limited.

Hereinafter, a method for preparing sulfonic acid-modified silica particles using colloidal silica by a sol-gel method, which are a preferred form of silica particles, will be described.

### (Step of Preparing Colloidal Silica)

Preparation of colloidal silica (raw material colloidal silica) by the sol-gel method can be performed using a conventionally known method, and specifically, colloidal silica can be obtained by performing a hydrolysis/condensation reaction in a reaction solvent using a hydrolyzable silicon compound (for example, alkoxysilane such as tetramethoxysilane, tetraethoxysilane, or tetraisopropoxysilane, or a derivative thereof) as a raw material. At this time, water or an organic solvent containing water can be used as the reaction solvent. Examples of the organic solvent include hydrophilic organic solvents such as alcohols such as methanol, ethanol, isopropanol, n-butanol, t-butanol, pentanol, ethylene glycol, propylene glycol, and 1,4-butanediol, and ketones such as acetone and methyl ethyl ketone. Among these organic solvents, alcohols such as methanol, ethanol, and isopropanol are preferably used, and from the viewpoint of post-treatment of the reaction solvent and the like, alcohols having the same alkyl group as alkyl group contained in the alkoxy group of the silicon compound as a raw material (for example, for tetramethoxysilane, methanol) are more preferably used. These organic solvents may be used singly or in combination of two or more kinds thereof.

It is preferable to adjust the reaction solvent to be alkaline by adding a basic catalyst to the reaction solvent of the hydrolysis/condensation reaction (Stober method). Thereby, the reaction solvent is preferably adjusted to pH 8 to 11, more preferably pH 8.5 to 10.5, and colloidal silica can be quickly formed. The basic catalyst is preferably an organic amine or ammonia from the viewpoint of preventing contamination of impurities.

In order to hydrolyze and condense a silicon compound in a reaction solvent, the silicon compound as a raw material may be added to the reaction solvent and stirred under a temperature condition of 0 to 100° C., preferably 0 to 50° C. By hydrolyzing and condensing a silicon compound in an organic solvent containing water while stirring the silicon compound, colloidal silica having a uniform particle size can be obtained. From the viewpoint of obtaining colloidal silica having a uniform particle size, it is preferable to remove an organic solvent coexisting with the colloidal silica so that the residual organic solvent concentration in the colloidal silica is less than 1% by mass. Here, “whether or not the residual organic solvent concentration in the colloidal silica is less than 1% by mass” is synonymous with “whether or not the organic solvent is detected in the colloidal silica” in the measurement method of the organic solvent concentration (methanol concentration in Examples) using gas chromatography described in Examples described later. That is, the above-described phrase “so that the residual organic solvent concentration in the colloidal silica is less than 1% by mass” can also be rephrased as “so that the organic solvent in the colloidal silica measured by the measurement method using gas chromatography described in Examples is the detection limit or less”.

Bu reducing the concentration of the organic solvent contained in the colloidal silica in this manner, an amount of microparticles contained in a raw material colloidal silica can be reduced.

Examples of method for removing the organic solvent coexisting with the colloidal silica include a method of heating a dispersion (silica sol) of the colloidal silica and distilling off the organic solvent. At this time, by substituting an organic solvent to be removed with water (heat concentrated water replacement), the liquid amount of the dispersion of the colloidal silica can be maintained. pH of the dispersion of the colloidal silica at the time of distilling off the organic solvent is preferably pH 7 or more. This has an advantage in that an amount of microparticles can be further reduced together with the distillation of the organic solvent.

### (Surface Modification Step)

A surface modification step preferably includes a first reaction step of heating the raw material colloidal silica in the presence of a silane coupling agent having a functional group (thiol group) capable of being chemically converted into a sulfonic acid group to obtain a reactant, and a second reaction step of converting the functional group (thiol group) into an organic acid group (sulfonic acid group).

### <<First Reaction Step>>

In the first reaction step, raw material colloidal silica is heated in the presence of a silane coupling agent having a functional group (thiol group) capable of being chemically converted into a sulfonic acid group. As a result, a reactant (a product in which a silane coupling agent having a thiol group is bonded to surface of silica particles) can be obtained.

As necessary, the raw material colloidal silica obtained as above may be subjected to various treatment steps before the first reaction step. As such a treatment step, for example, a step of reducing viscosity of raw material colloidal silica is exemplified. Examples of the step of reducing viscosity of raw material colloidal silica include a step of adding an alkali solution (aqueous solution of various bases such as ammonia water) or an organic solvent to raw material colloidal silica. An amount of the alkali solution or the organic solvent added at this time is not particularly limited, and may be appropriately set in consideration of viscosity of raw material colloidal silica obtained after the addition. As described above, by performing the step of reducing viscosity of raw material colloidal silica, there are advantages in that the initial dispersibility of coupling agent in the colloidal silica can be improved and aggregation of silica particles can be suppressed.

In the first reaction step, raw material colloidal silica is heated in the presence of a silane coupling agent having a functional group capable of being chemically converted into a sulfonic acid group. Examples of the silane coupling agent having a functional group capable of being chemically converted into a sulfonic acid group include the above-described silane coupling agent having a thiol group.

When the method for removing the organic solvent coexisting with the colloidal silica is adopted in the preparation step of colloidal silica, the raw material colloidal silica does not substantially contain organic solvent, and dispersing medium of the raw material colloidal silica is substantially composed of water. On the other hand, since a silane coupling agent is hardly dissolved in water, it is preferable to use a certain amount or more of an organic solvent (hydrophilic solvent) for the purpose of dissolving a silane coupling agent. Examples of such an organic solvent (hydrophilic solvent) include the above-described organic solvents such as methanol, ethanol, and isopropanol. Among them, it is preferable to use the same alcohol as the alcohol produced by hydrolysis of the silicon compound described above. Such an organic solvent (hydrophilic solvent) may be added to raw material colloidal silica, or a silane coupling agent may be mixed with the organic solvent (hydrophilic solvent) in advance to obtain a mixed liquid, and the mixed liquid may be added to raw material colloidal silica, but the latter method is more preferable.

An addition amount of a silane coupling agent used in the first reaction step is adjusted so as to be the value of the surface coverage. Specifically, when the silane coupling agent is 3-mercaptopropyl trimethoxysilane, an addition amount (concentration) of the coupling agent (3-mercaptopropyl trimethoxysilane) with respect to the total mass (total mass of solid content) of raw material silica particles is preferably 0.00500% by mass or more and less than 1.00% by mass, more preferably 0.0500% by mass or more and 0.500% by mass or less, further preferably 0.100% by mass or more and less than 0.500% by mass, particularly preferably more than 0.100% by mass and less than 0.400% by mass, and most preferably 0.150% by mass or more and 0.300% by mass or less. When the addition amount of the coupling agent in the first reaction step is set to the above range, the surface coverage of the obtained sulfonic acid-modified silica particles falls within a suitable range. As a result, when the sulfonic acid-modified silica particles are used as a polishing agent (abrasive grains in a polishing composition), the polishing removal rate of the silicon oxide film can be improved, and the silicon oxide film and the silicon nitride film can be polished at the substantially same rate.

In raw material silica particles used in the first reaction step, the number of silanol groups present on the surface (ρₛ: the number of silanol groups per unit area in silica particles) is preferably 2.50/nm² or more and 10.0/nm² or less, more preferably 3.00/nm² or more and 8.00/nm² or less, further preferably 3.20/nm² or more and 7.00/nm² or less, particularly preferably 3.50/nm² or more and 6.00/nm² or less, and most preferably 3.60/nm² or more and 5.00/nm² or less. When raw material silica particles have the number of silanol groups (ρₛ) described above, the polishing removal rate of the silicon oxide film is further improved, and the polishing removal rate ratio of SiO₂/SiN can be set to about 1.2 or more and 1.4 or less, which is preferable. The number of silanol groups (ρₛ) of raw material silica particles is a value obtained by the above Formula (2), and specifically, a value determined by the measurement method and the calculation method described in Examples described later is adopted.

An amount of an organic solvent used to dissolve a silane coupling agent is preferably about 500% by mass or more and 10000% by mass or less, and more preferably 1000% by mass or more and 5000% by mass or less, with respect to the total mass of the silane coupling agent.

A temperature at which a silane coupling agent is added is not limited, but is preferably in a range from normal temperature (about 20° C.) to the boiling point of the reaction solvent. The reaction time is also not limited, but is preferably 10 minutes or more and 10 hours or less, and more preferably 1 hour or more and 7 hours or less. However, from the viewpoint of terminating hydrolysis of the coupling agent, the first reaction step is preferably carried out under the condition that the temperature condition of 90° C. or higher is continued for 30 minutes or more.

### <<Second Reaction Step>>

In the second reaction step, the reactant (a product in which a silane coupling agent having a thiol group is bonded to the surface of silica particles) obtained in the first reaction step is treated. Thereby, the thiol group of the silane coupling agent is converted into a sulfonic acid group.

Specifically, by subjecting the reactant (silica particles in which a silane coupling agent having a thiol group is bonded to the surface thereof) to an oxidation treatment, the thiol group present on the surface of the silane coupling agent can be oxidized. Thereby, the thiol group is converted into a sulfonic acid group.

In order to subject the reactant to an oxidation treatment, for example, the reactant may be reacted with an oxidizing agent. Examples of the oxidizing agent include nitric acid, hydrogen peroxide, oxygen, ozone, organic peracid (percarboxylic acid), bromine, hypochlorite, potassium permanganate, chromic acid, and the like. Among these oxidizing agents, hydrogen peroxide and organic peracid (peracetic acid, or perbenzoic acid) are preferable from the viewpoint of relatively easy handling and favorable oxidation yield. It is most preferable to use hydrogen peroxide in consideration of a substance by-produced in the reaction. From the viewpoint of securing an amount necessary for the reaction and reducing the remaining oxidizing agent, an addition amount of the oxidizing agent is preferably 3 to 5 mol times the amount of silane coupling agent. When the addition amount of the oxidizing agent is set to a value within such a range, the residual oxidizing agent concentration in the obtained sulfonic acid-modified silica particles can be minimized.

When the sulfonic acid-modified silica particles obtained according to the above method contain a solvent other than water, a dispersing medium mainly containing a reaction solvent may be substituted with water as necessary in order to enhance long-term storage stability of the sulfonic acid-modified silica particles. The water substitution may be performed after the addition of the silane coupling agent and before the addition of the oxidizing agent. The method for substituting a solvent other than water with water is not particularly limited, and examples thereof include a method in which water is added dropwise by a certain amount while heating the sulfonic acid-modified silica particles. A method in which the sulfonic acid-modified silica particles are separated from a solvent other than water by precipitation, separation, centrifugation, or the like, and then redispersed in water is also exemplified.

Although the method for preparing the sulfonic acid-modified silica particles has been specifically described above, the method can also be applied to the preparation of surface-modified silica particles having another organic acid group.

Therefore, as still another aspect of the present invention, the following method for producing a polishing composition can be provided:

1. A method for producing a polishing composition, the method including:
a surface modification step of obtaining surface-modified silica particles by performing a first reaction step of heating raw material silica particles in the presence of a silane coupling agent having a functional group capable of being chemically converted into an organic acid group to obtain a reactant and a second reaction step of converting the functional group into an organic acid group; and
a mixing step of mixing the surface-modified silica particles and a dispersing medium,
in which in the first reaction step, an addition amount of the silane coupling agent is 0.00500% by mass or more and less than 1.00% by mass with respect to the total mass of the raw material silica particles,
the mixing step includes adjusting pH of the polishing composition to less than 5.0, and
an average primary particle diameter of the surface-modified silica particles is 20 nm or more and 100 nm or less;

2. The production method described in above item 1., in which the number of silanol groups present on a surface of the raw material silica particles (ρₛ: the number of silanol groups per unit area in raw material silica particles) is 2.50/nm² or more and 10.0/nm² or less;

3. The production method described in above item 1, or 2., in which the mixing step includes further mixing an ammonium salt;

4. The production method described in above item 3., in which the ammonium salt includes at least one selected from the group consisting of ammonium sulfate, ammonium nitrate, diammonium hydrogen citrate, and triammonium citrate;

5. The production method described in any one of above items 1. to 4., in which the mixing step includes further mixing a pH adjusting agent;

6. The production method described in any one of above items 1. to 5., in which the mixing step includes adjusting pH of the polishing composition to 1.5 or more and less than 4.0;

7. The production method described in any one of above items 1. to 6., further including a preparation step of colloidal silica by a sol-gel method before the first reaction step, in which the preparation step includes removing an organic solvent such that a residual organic solvent concentration in the colloidal silica is less than 1% by mass;

8. The production method described in any one of above items 1. to 7., in which an average secondary particle diameter of the surface-modified silica particles is 35 nm or more and 250 nm or less;

9. The production method described in any one of above items 1. to 8., in which the average primary particle diameter of the surface-modified silica particles is 50 nm or less;

10. The production method described in any one of above items 1. to 9., in which the organic acid group is a sulfonic acid group; and

11. The production method described in above item 10., in which the silane coupling agent is an alkoxysilane compound having a thiol group.

In the above aspect, the range described in the section of <<First reaction step>> is cited as preferable ranges of the addition amount of the silane coupling agent with respect to the total mass of the raw material silica particles and the number of silanol groups present on the surface of the raw material silica particles. In the above aspect, for preferable ranges of the average primary particle diameter and the average secondary particle diameter of the surface-modified silica particles, specific examples of the dispersing medium, the ammonium salt, and the pH adjusting agent, the concentration of each component, a preferable range of pH of the polishing composition, and the like, the description described in each of the sections of [Abrasive grains], [Dispersing medium], [pH adjusting agent], [Ammonium salt], and [pH] is incorporated.

### <Object to be Polished>

According to an embodiment of the present invention, an object to be polished contains at least one of silicon oxide (SiO₂) and silicon nitride (SiN). According to another embodiment of the present invention, an object to be polished contains silicon oxide (SiO₂) and silicon nitride (SiN). By applying the polishing composition of the embodiment of the present invention to such an object to be polished, polishing can be performed at the same rate and at a high rate. That is, the polishing composition according to the present invention is preferably used for polishing an object to be polished containing silicon oxide and silicon nitride.

In an embodiment of the present invention, as the silicon oxide (SiO₂) contained in an object to be polished, silicon oxide (SiO₂) derived from tetraethyl orthosilicate (TEOS) is suitable. According to an embodiment of the present invention, the object to be polished further contains polysilicon. According to an embodiment of the present invention, the use application of the polishing composition is not limited, but the polishing composition is preferably used for a semiconductor substrate.

### <Polishing Method>

Another embodiment of the present invention relates to a polishing method including a step of polishing an object to be polished by using the above-described polishing composition. A preferred example of the object to be polished according to the present embodiment is the same described in <Object to be polished>. For example, it is preferable to polish an object to be polished containing silicon oxide and silicon nitride on a surface to be polished. That is, a preferred aspect of the polishing method according to the present invention includes polishing an object to be polished containing silicon oxide and silicon nitride by using the above-described polishing composition.

When an object to be polished is polished by using the polishing composition, polishing can be performed using an apparatus and conditions used for usual polishing. Examples of a general polishing apparatus include a single side polishing apparatus and a double side polishing apparatus. In a single side polishing apparatus, an object to be polished is typically held with a retainer referred to as carrier, and a platen with a polishing pad attached is pressed against one side of the object to be polished and rotated, while the polishing composition is supplied from above, so that the one side of the object to be polished is polished. In a double side polishing apparatus, an object to be polished is typically held with a retainer referred to as carrier, and platens with a polishing pad attached are pressed against opposing surfaces of the object to be polished and rotated in the opposing directions, while the polishing composition is supplied from above, so that both sides of the object to be polished are polished. At this time, polishing is performed through a physical action caused by friction between a polishing pad together with the polishing composition and an object to be polished, and through a chemical action on an object to be polished caused by the polishing composition. As the polishing pad, a porous material of nonwoven fabric, polyurethane, suede, or the like can be used without particular limitation. The polishing pad is preferably processed such that a polishing liquid is accumulated.

Examples of polishing conditions include a polishing load, a rotation speed of platen, a rotation speed of carrier, a flow rate of the polishing composition, a polishing time, and the like. Although these polishing conditions are not particularly limited, for example, a polishing load per unit area of an object to be polished is preferably 0.1 psi (0.69 kPa) or more and 10 psi (69 kPa) or less, more preferably 0.5 psi (3.5 kPa) or more and 8.0 psi (55 kPa) or less, and further preferably 1.0 psi (6.9 kPa) or more and 6.0 psi (41 kPa) or less. In general, as the load increases, the friction force by abrasive grains increases, and the mechanical processing force is improved, so that the polishing removal rate increases. Within this range, a sufficient polishing removal rate is exhibited, and damage to an object to be polished and occurrence of defects such as surface scratches caused by the load can be suppressed. The rotation speed of platen and the rotation speed of carrier are preferably 10 rpm (0.17 s⁻¹) or more and 500 rpm (8.3 s⁻¹) or less. The supply amount of the polishing composition may be a supply amount (flow rate) at which the polishing composition covers the whole of an object to be polished, and may be adjusted depending on the conditions such as the size of the object to be polished. The method of supplying the polishing composition to the polishing pad is not particularly limited, and for example, a method of continuously supplying the polishing composition by a pump or the like is adopted. Although a processing time is not particularly limited as long as desired processing results are obtained, a less time resulting from a high polishing removal rate is preferred.

Still another embodiment of the present invention relates to a method for producing a polished object, including a step of polishing an object to be polished by the polishing method described above. A preferred example of the object to be polished according to the present embodiment is the same described in <Object to be polished>. As a preferred example, there is mentioned a method for producing an electronic circuit board, including polishing an object to be polished containing silicon oxide and silicon nitride by the above-described polishing method.

Although the embodiments of the present invention have been described in detail, this is illustrative and exemplary and not restrictive, and it is clear that the scope of the present invention should be interpreted by the appended claims.

The present invention includes the following aspects and embodiments:

[1]A polishing composition containing abrasive grains and a dispersing medium, in which pH is less than 5.0, the abrasive grains are surface-modified silica particles in which an organic acid is immobilized on a surface thereof, a surface coverage of silanol groups present on a surface of the surface-modified silica particles is more than 0% and 6.0% or less, and an average primary particle diameter of the abrasive grains is 20 nm or more and 100 nm or less;

[2] The polishing composition described in above item [1], in which the surface coverage is 0.050% or more and 5.0% or less;

[3] The polishing composition described in above item [2], in which the surface coverage is 0.50% or more and less than 3.6%;

[4] The polishing composition described in any one of above items [1] to [3], in which pH is 1.5 or more and less than 4.0;

[5] The polishing composition described in any one of above items [1] to [4], further containing an ammonium salt;

[6] The polishing composition described in above item [5], in which the ammonium salt includes at least one selected from the group consisting of ammonium sulfate, ammonium nitrate, diammonium hydrogen citrate, and triammonium citrate;

[7] The polishing composition described in any one of above items [1] to [6], in which an average secondary particle diameter of the abrasive grains is 35 nm or more and 250 nm or less;

[8] The polishing composition described in any one of above items [1] to [7], in which the average primary particle diameter of the abrasive grains is 50 nm or less;

[9] The polishing composition described in any one of above items [1] to [8], in which the abrasive grains are sulfonic acid-modified silica particles in which a sulfonic acid group is immobilized on a surface thereof;

[10] The polishing composition described in any one of above items [1] to [9], which is used for polishing an object to be polished containing silicon oxide and silicon nitride; and

[11]A polishing method including polishing an object to be polished containing silicon oxide and silicon nitride by using the polishing composition described in any one of above items [1] to [10].

### EXAMPLES

The present invention will be described in more detail with the following Examples and Comparative Examples. However, the technical scope of the present invention is not limited only to the following Examples. Unless otherwise specified, “%” and “part(s)” mean “% by mass” and “part(s) by mass”. In the following Examples, unless otherwise specified, operations and evaluations were performed under the conditions of room temperature (25° C.)/relative humidity of 40% RH or more and 50% RH or less.

### <Preparation of Polishing Composition>

### 1-1. Preparation of Abrasive Grains

### Production Example 1

Sulfonic acid-modified silica particles (surface-modified silica 1) as abrasive grains were obtained according to the following procedure.

### (Step of Preparing Raw Material Colloidal Silica Dispersion (Unmodified Silica Particles))

In a flask, 4080 g of methanol, 610 g of water, and 168 g of a 29% by mass aqueous ammonia solution were mixed, the liquid temperature was maintained at 20° C., and a mixed solution of 135 g of methanol and 508 g of tetramethoxysilane (TMOS) was added dropwise thereto for a dropwise addition time of 25 minutes. Thereafter, the resultant mixture was subjected to heat concentrated water replacement under a condition of pH 7 or more, and 1000 g of 19.5% by mass silica sol was obtained (average primary particle diameter: about 24 nm; average secondary particle diameter: about 41 nm; type of silica particles in Table 1: B). It was confirmed by gas chromatography (the following condition 1) that the methanol concentration at this time was less than 1% by mass (detection limit or less).

### (Condition 1: Measurement Condition of Methanol Concentration Using Gas Chromatography)

Apparatus: Gas chromatography GC-14B (manufactured by SHIMADZU CORPORATION)

Measurement: 4 μL of sample was withdrawn using a 10 μL syringe and injected into the apparatus. The methanol concentration was calculated from the moisture amount and the methanol amount obtained by the measurement.

### (Surface Modification Step)

Subsequently, to 1000 g (195 g in terms of silica solid content) of the silica sol obtained above, 0.0195 g of 3-mercaptopropyl trimethoxysilane (coupling agent, product name: KBM-803, manufactured by Shin-Etsu Chemical Co., Ltd.) (coupling agent concentration with respect to the total mass of silica solid content: 0.0100% by mass) separately mixed with 0.371 g of methanol was added dropwise at a flow rate of 1 mL/min. Thereafter, heating was performed, and pure water replacement was performed for 3 hours after boiling.

Next, for cooling, the reaction solution was left to stand still overnight, 0.0343 g (3 mol with respect to 1 mol of the silane coupling agent) of 30% by mass hydrogen peroxide water was added thereto, and the mixture was boiled again. Thereafter, pure water replacement was performed for 2 hours, followed by cooling to room temperature (25° C.) to obtain sulfonic acid-modified silica particles (surface-modified silica 1).

### Production Examples 2 to 10

Sulfonic acid-modified silica particles (surface-modified silicas 2 to 10) were obtained by the same procedure as in Production Example 1, except that, in the section of (Surface modification step) of Production Example 1, the addition amount (mass ratio with respect to silica solid content) of 3-mercaptopropyl trimethoxysilane as a silane coupling agent was changed to each of the values described in Table 1 (value of coupling agent concentration) and the addition amount of hydrogen peroxide water was changed (specifically, the addition amount of hydrogen peroxide water was adjusted so as to have a molar concentration three times the molar concentration of the silane coupling agent).

### Production Examples 11 to 14

Sulfonic acid-modified silica particles (surface-modified silicas 11 to 14) were obtained by the same procedure as in Production Example 4, except that in Production Example 4 (production of surface-modified silica 4), the colloidal silica dispersion used as a raw material was changed as follows, and the addition amount (mass ratio with respect to silica solid content) of 3-mercaptopropyl trimethoxysilane as a silane coupling agent was changed to each of the values described in Table 1 (value of coupling agent concentration).
Production Example 11: manufactured by FUSO CHEMICAL CO., LTD. (average primary particle diameter: about 15.0 nm; average secondary particle diameter: about 40.0 nm; type of silica particles in Table 1: C)
Production Example 12: manufactured by FUSO CHEMICAL CO., LTD. (average primary particle diameter: about 35.0 nm; average secondary particle diameter: about 70.0 nm; type of silica particles in Table 1: A)
Production Example 13: manufactured by FUSO CHEMICAL CO., LTD. (average primary particle diameter: about 75.0 nm; average secondary particle diameter: about 125.0 nm; type of silica particles in Table 1: D)
Production Example 14: manufactured by FUSO CHEMICAL CO., LTD. (average primary particle diameter: about 90.0 nm; average secondary particle diameter: about 220.0 nm; type of silica particles in Table 1: E)

The surface-modified silicas 1 to 14 obtained as described above were subjected to the following analysis. The obtained results are shown in Tables 1 and 2 below.

### (Measurement of Particle Size)

The average primary particle diameter of the abrasive grains was calculated from the specific surface area of the abrasive grains measured by the BET method using “Macsorb (registered trademark) HM model-1210” manufactured by Mountech Co., Ltd. and the density of the abrasive grains. The average secondary particle diameter of the abrasive grains was measured by a dynamic light scattering particle size and particle size distribution apparatus UPA-UT151 manufactured by NIKKISO CO., LTD.

### (Measurement of Surface Coverage)

The surface coverage (“coverage” in Table 1) of the abrasive grains (surface-modified silica particles) was calculated based on the following Formula (1) after each parameter was measured or calculated by the measurement method or the calculation method described later.

$$\begin{matrix}[ Mathematical Formula 3 ] & \\ Surface coverage ( \% ) = \frac{C \times {N}_{A}}{Mc \times {ρ}_{S} \times A} \times {10}^{- 20} \times 100 & Formula ( 1 )\end{matrix}$$

In the above Formula (1),
C represents concentration of a silane coupling agent used at the time of surface modification (mass concentration with respect to the total mass of raw material silica particles) [% by mass];
N_{A} represents the Avogadro constant (6.022×10²³) [number/mol];
Mc represents molar mass (in the present example, 202.26) [g/mol] of the silane coupling agent in a completely oxidized state;
ρₛ represents the number of silanol groups per unit area in silica particles in a state where surface modification is not performed (average silanol group density) [number/nm²]; and A represents a BET specific surface area [m²/g] of silica particles in silica particles in a state where surface modification is not performed.
ρₛ and A in the above Formula (1) were determined as follows.
   <<Measurement of Number of Silanol Groups (ρₛ)>>

The number of silanol groups per unit surface area of the silica particles can be calculated by the Sears method using neutralization titration described in Analytical Chemistry by G. W. Sears, vol. 28, No. 12, 1956, 1982 to 1983. Specifically, the number of silanol groups per unit surface area (unit: number/nm²) in the silica particles in a state where surface modification is not performed was calculated based on the following Formula (2).

$$\begin{matrix}[ Mathematical Formula 4 ] & \\ {ρ}_{s} = \frac{c \times a \times {N}_{A}}{m \times {A}^{′}} & Formula ( 2 )\end{matrix}$$

In the above Formula (2),
ρₛ represents the number of silanol groups (average silanol group density) [number/nm²] in silica particles in a state where surface modification is not performed;
c represents concentration [mol/L] of a sodium hydroxide solution used for titration;
a represents volume [L] of the sodium hydroxide solution required to adjust pH from 4.0 to 9.0;
N_{A} represents the Avogadro constant (6.022×10²³) [number/mol];
m represents the total mass (solid content) [g] of silica particles; and
A′ represents a BET specific surface area [nm²/g] of silica particles in silica particles in a state where surface modification is not performed.

More specifically, first, 1.50 g of silica particles (silica particles before surface modification) as a solid content was collected in a 200 mL beaker, 100 mL of pure water was added to form a slurry, and then 1 N hydrochloric acid was added to adjust pH of the slurry to about 3.0 to 3.5. Next, 30 g of sodium chloride was added and dissolved, and then pure water was added until the slurry became 150 mL. To the slurry, 0.1 N sodium hydroxide was added dropwise at 25° C. to adjust pH to 4.0, and the volume a [L] of the 0.1 N sodium hydroxide solution required to raise pH from 4.0 to 9.0 was measured by pH titration. At this time, pH of the slurry was measured using an automatic titrator (Model No.: COM-1700 manufactured by HIPANUMA Co., Ltd.).

### <<Measurement of BET Specific Surface Area (A, A′)>>

The BET specific surface areas A [m²/g] and A′ [nm²/g] of the abrasive grains (silica particles) were measured using “Macsorb (registered trademark) HM model-1210” manufactured by Mountech Co., Ltd.

### 1-2. Preparation of Polishing Composition

### Comparative Example 1

Colloidal silica (unmodified silica 1; type of silica particles in Table 1: B) as abrasive grains was mixed with ion-exchanged water as a dispersing medium so as to have concentration of 3.72% by mass, and maleic acid as a pH adjusting agent was further added to adjust pH, thereby preparing a polishing composition. In Table 1, the “coupling agent concentration” is described as “0.00% by mass” for comparison with Examples, but this description indicates that colloidal silica without surface modification was used.

### Comparative Example 2

A polishing composition was prepared by the same procedure as in Comparative Example 1, except that ammonium sulfate was further added as an additive so as to have a concentration of 37.2 mM in Comparative Example 1.

### Example 1

The colloidal silica (surface-modified silica 1) obtained in Production Example 1 as abrasive grains and ammonium sulfate as an additive were mixed in pure water as a dispersing medium, and maleic acid as a pH adjusting agent was further added thereto to adjust pH to 3.0, thereby obtaining a polishing composition. At this time, the colloidal silica (surface-modified silica 1) was added so as to have concentration of 3.72% by mass and ammonium sulfate was added so as to have concentration of 37.2 mM.

### Examples 2 to 6 and Comparative Examples 3 to 6

Polishing compositions were prepared by the same procedure as in Example 1, except that colloidal silica as abrasive grains in Example 1 was changed to surface-modified silicas 2 to 10 obtained in Production Examples 2 to 10 described above, respectively. At this time, the pH of each polishing composition was adjusted to be within a range of 2.7 to 3.0 (pH=about 3).

### Example 7

A polishing composition was prepared by the same procedure as in Example 4, except that ammonium sulfate as an additive was not added in Example 4.

### Examples 8 to 10 and Comparative Examples 7 to 9

Polishing compositions were prepared by the same procedure as in Example 4, except that in Example 4, the addition amount of maleic acid as a pH adjusting agent was changed, and pH of the polishing composition was adjusted to the value described in Table 2.

### Comparative Example 10 and Examples 11 to 13

Polishing compositions were prepared by the same procedure as in Example 4, except that colloidal silica as abrasive grains in Example 4 was changed to surface-modified silicas 11 to 14 obtained in Production Examples 11 to 14 described above, respectively.

The polishing compositions according to Examples and Comparative Examples obtained as described above were subjected to the following analysis. The obtained results are shown in Table 2 below.

### (Measurement of pH)

pH of each polishing composition (liquid temperature: 25° C.) was checked by a pH meter (Model No.: LAQUA (registered trademark) manufactured by HORIBA, Ltd.).

### (Measurement of Electrical Conductivity)

The electrical conductivity (EC) of each polishing composition (liquid temperature: 25° C.) was measured by a tabletop-type electrical conductivity meter (Model No.: DS-71 manufactured by HORIBA, Ltd.).

### <Evaluation>

### [Polishing Removal Rate (Polishing Rate)]

### (CMP Step)

A surface of an object to be polished was polished under the following conditions using each polishing composition. As an object to be polished, silicon wafers (200 mm, blanket wafer) having a silicon oxide (SiO₂) film having a thickness of 10,000 Å and a silicon nitride (SiN) film having a thickness of 3,500 Å respectively formed on a surface thereof were used. A coupon obtained by cutting each wafer into chips of 60 mm×60 mm was used as a test piece, and the polishing removal rates of the SiO₂ film and the SiN film at the time of being polished under the following conditions were measured.

### <<Polishing Apparatus and Polishing Conditions>>

Polishing apparatus: Small-sized table-top polishing machine EJ380IN manufactured by Engis Japan Corporation
Polishing pad: Hard polyurethane pad IC1000 manufactured by Nitta DuPont Co., Ltd.
Polishing pressure: 3.0 psi (1 psi=6894.76 Pa)
Rotation speed of polishing table (platen): 60 rpm
Rotation speed of head (carrier): 60 rpm
Flow rate of polishing composition (slurry): 100 mL/min
Polishing time: 1 min

### (Measurement Method)

The polishing removal rate was evaluated by determining the film thicknesses of the object to be polished before and after polishing by a light interference type film thickness measurement apparatus (LAMBDA ACE VM-2030 manufactured by SCREEN Semiconductor Solutions Co., Ltd.), and dividing a difference in film thickness before and after polishing by the polishing time (see the following Formula (3)).

$$\begin{matrix}[ Mathematical Formula 5 ] & \\ Polishing removal rate ( \mathring{A} / min ) = \frac{[ Film thickness ( \mathring{A} ) of object to be polished before polishing ] - [ Film thickness ( \mathring{A} ) of object to be polished after polishing ]}{[ Polishing time ( min ) ]} & Formula ( 3 )\end{matrix}$$

The results obtained by the above measurement are shown in Table 2. From the obtained results, the polishing removal rate ratio (SiO₂/SiN) of the silicon oxide film to the polishing removal rate of the silicon nitride film was calculated. The results thereof are also shown in Table 2.

As the evaluation criteria, when the value of the polishing removal rate of the silicon oxide film is 450 Å/min or more and the value of the polishing removal rate ratio (SiO₂/SiN) is 1.0 or more and 2.3 or less, it is determined to be acceptable. The value of the polishing removal rate of the silicon oxide film is preferably 500 Å/min or more, more preferably 510 Å/min or more, and particularly preferably 550 Å/min or more. The upper limit thereof is not particularly limited, but is substantially 1000 Å/min or less. The value of the polishing removal rate ratio (SiO₂/SiN) is preferably 1.1 or more and 1.5 or less, more preferably 1.2 or more and 1.4 or less, and particularly preferably 1.3.

TABLE 1

| | Conditions at the time of | | | | | | |
|---|---|---|---|---|---|---|---|
| | preparing abrasive grains | | | | | | |
| | | Silica | | Abrasive grains | | | |
| | | particle | Coupling | | Abrasive | | |
| | | Concentration | agent | | grain | | Average |
| | | in raw | concentration [symbol] | | concentration in | Number of | Primary |
| | Silica | material | [symbol] | | composition | [symbol] | particle |
| | particle | [% by | [% by | | [% by | [number/ | diameter |
| | type | mass] | mass] | | mass] | [symbol] ] | [ [symbol] ] |
| Comparative | B | [symbol] | 0.00 | Unmodified silica 1 | 3.72 | 3.70 | 24.0 |
| Example 1 | | | | | | | |
| Comparative | B | [symbol] | 0.00 | Unmodified silica 1 | 3.72 | 3.70 | 24.0 |
| Example 2 | | | | | | | |
| Example 1 | B | [symbol] | [symbol] | Surface-modified silica 1 | 3.72 | [symbol] | 24.0 |
| Example 2 | B | [symbol] | 0.100 | Surface-modified silica 2 | 3.72 | [symbol] | 24.0 |
| Example 3 | B | [symbol] | 0.125 | Surface-modified silica 3 | 3.72 | [symbol] | 24.0 |
| Example 4 | B | [symbol] | 0.250 | Surface-modified silica 4 | 3.72 | [symbol] | 24.0 |
| Example 5 | B | [symbol] | 0.400 | Surface-modified silica 5 | 3.72 | [symbol] | 24.0 |
| Example 6 | B | [symbol] | [symbol] | Surface-modified silica 6 | 3.72 | [symbol] | 24.0 |
| Comparative | B | [symbol] | 1.00 | Surface-modified silica 7 | 3.72 | [symbol] | 24.0 |
| Example 3 | | | | | | | |
| Comparative | B | [symbol] | 1.25 | Surface-modified silica 8 | 3.72 | [symbol] | 24.0 |
| Example 4 | | | | | | | |
| Comparative | B | [symbol] | 1.50 | Surface-modified silica 9 | 3.72 | [symbol] | 24.0 |
| Example 5 | | | | | | | |
| Comparative | B | [symbol] | 2.00 | Surface-modified silica 10 | 3.72 | [symbol] | 24.0 |
| Example 6 | | | | | | | |
| Example 7 | B | [symbol] | 0.250 | Surface-modified silica 4 | 3.72 | [symbol] | 24.0 |
| Example 8 | B | [symbol] | 0.250 | Surface-modified silica 4 | 3.72 | [symbol] | 24.0 |
| Example 9 | B | [symbol] | 0.250 | Surface-modified silica 4 | 3.72 | [symbol] | 24.0 |
| Exemple 10 | B | [symbol] | 0.250 | Surface-modified silica 4 | 3.72 | [symbol] | 24.0 |
| Comparative | B | [symbol] | 0.250 | Surface-modified silica 4 | 3.72 | [symbol] | 24.0 |
| Example 7 | | | | | | | |
| Comparative | B | [symbol] | 0.250 | Surface-modified silica 4 | 3.72 | [symbol] | 24.0 |
| Example 8 | | | | | | | |
| Comparative | B | [symbol] | 0.250 | Surface-modified silica 4 | 3.72 | [symbol] | 24.0 |
| Example 9 | | | | | | | |
| Comparative | C | 12.5 | [symbol] | Surface-modified silica 11 | 3.72 | 2.36 | 13.6 |
| Example 10 | | | | | | | |
| Example 11 | A | [symbol] | 0.250 | Surface-modified silica 12 | 3.72 | 5.70 | [symbol] |
| Example 12 | D | [symbol] | [symbol] | Surface-modified silica 13 | 3.72 | 6.58 | [symbol] |
| Example 13 | E | [symbol] | 0.150 | Surface-modified silica 14 | 3.72 | 7.90 | [symbol] |

| | Abrasive grains | | | | | |
|---|---|---|---|---|---|---|
| | Average | BET specific | | | | |
| | secondary | surface | | | | [symbol] |
| | particle | area | | Additive | | agent |
| | diameter | ( [symbol] ) | Coverage | Compound | Concentration | Compound |
| | [ [symbol] ] | [ [symbol] ] | [%] | name | [ [symbol] ] | name |
| Comparative | 41.1 | 113.5 | 0.0 | — | 0 | Maleic acid |
| Example 1 | | | | | | |
| Comparative | 41.1 | 113.5 | 0.0 | Ammonium sulfate | 37.2 | Maleic acid |
| Example 2 | | | | | | |
| Example 1 | 41.1 | 113.5 | 0.071 | Ammonium sulfate | 37.2 | Maleic acid |
| Example 2 | 41.1 | 113.5 | 0.71 | Ammonium sulfate | 37.2 | Maleic acid |
| Example 3 | 41.1 | 113.5 | 0.89 | Ammonium sulfate | 37.2 | Maleic acid |
| Example 4 | 41.1 | 113.5 | 1.8 | Ammonium sulfate | 37.2 | Maleic acid |
| Example 5 | 41.1 | 113.5 | 2.9 | Ammonium sulfate | 37.2 | Maleic acid |
| Example 6 | 41.1 | 113.5 | 3.8 | Ammonium sulfate | 37.2 | Maleic acid |
| Comparative | 41.1 | 113.5 | 7.1 | Ammonium sulfate | 37.2 | Maleic acid |
| Example 3 | | | | | | |
| Comparative | 41.1 | 113.5 | [symbol] | Ammonium sulfate | 37.2 | Maleic acid |
| Example 4 | | | | | | |
| Comparative | 41.1 | 113.5 | 10.7 | Ammonium sulfate | 37.2 | Maleic acid |
| Example 5 | | | | | | |
| Comparative | 41.1 | 113.5 | 14.3 | Ammonium sulfate | 37.2 | Maleic acid |
| Example 6 | | | | | | |
| Example 7 | 41.1 | 113.5 | 1.8 | — | 0 | Maleic acid |
| Example 8 | 41.1 | 113.5 | 1.8 | Ammonium sulfate | 37.2 | Maleic acid |
| Example 9 | 41.1 | 113.5 | 1.8 | Ammonium sulfate | 37.2 | Maleic acid |
| Exemple 10 | 41.1 | 113.5 | 1.8 | Ammonium sulfate | 37.2 | Maleic acid |
| Comparative | 41.1 | 113.5 | 1.8 | Ammonium sulfate | 37.2 | Maleic acid |
| Example 7 | | | | | | |
| Comparative | 41.1 | 113.5 | 1.8 | Ammonium sulfate | 37.2 | Maleic acid |
| Example 8 | | | | | | |
| Comparative | 41.1 | 113.5 | 1.8 | Ammonium sulfate | 37.2 | Maleic acid |
| Example 9 | | | | | | |
| Comparative | 30.6 | [symbol] | 2.3 | Ammonium sulfate | 37.2 | Maleic acid |
| Example 10 | | | | | | |
| Example 11 | [symbol] | [symbol] | [symbol] | Ammonium sulfate | 37.2 | Maleic acid |
| Example 12 | [symbol] | 34.83 | 2.0 | Ammonium sulfate | 37.2 | Maleic acid |
| Example 13 | 201.9 | 30.47 | 1.9 | Ammonium sulfate | 37.2 | Maleic acid |

[symbol]

indicates data missing or illegible when filed

TABLE 2

| | Abrasive grains | | | | | | | | | |
|---|---|---|---|---|---|---|---|---|---|---|
| | | Average | Average | | | | | | | |
| | | primary | secondary | | | Physical | | Polishing | | |
| | | particle | particle | | Additive | properties | | removal rate | | |
| | | diameter | diameter | Coverage | Compound | | EC | [symbol] | SiN | Selectivity |
| | Type | [ [symbol] ] | [ [symbol] ] | [%] | name | pH | [ [symbol] ] | [ [symbol] ] | [ [symbol] ] | [symbol] |
| Comparative | Unmodified silica 1 | 24.0 | 41.1 | 0.00 | — | 2.5 | [symbol] | 312.0 | 91.2 | 3.4 |
| Example 1 | | | | | | | | | | |
| Comparative | Unmodified silica 1 | 24.0 | 41.1 | 0.00 | Ammonium sulfate | 3.0 | [symbol] | [symbol] | 318.0 | 1.3 |
| Example 2 | | | | | | | | | | |
| Example 1 | Surface-modified silica 1 | 24.0 | 41.1 | 0.071 | Ammonium sulfate | 3.0 | [symbol] | [symbol] | [symbol] | 1.3 |
| Example 2 | Surface-modified silica 2 | 24.0 | 41.1 | 0.71 | Ammonium sulfate | 3.0 | [symbol] | [symbol] | 429.1 | 1.4 |
| Example 3 | Surface-modified silica 3 | 24.0 | 41.1 | [symbol] | Ammonium sulfate | 2.9 | [symbol] | [symbol] | 435.8 | 1.4 |
| Example 4 | Surface-modified silica 4 | 24.0 | 41.1 | [symbol] | Ammonium sulfate | 2.9 | [symbol] | [symbol] | 445.7 | 1.3 |
| Example 5 | Surface-modified silica 5 | 24.0 | 41.1 | 2.9 | Ammonium sulfate | 2.9 | [symbol] | 513.0 | 425.1 | 1.2 |
| Example 6 | Surface-modified silica 6 | 24.0 | 41.1 | 3.6 | Ammonium sulfate | 2.9 | [symbol] | [symbol] | [symbol] | 1.0 |
| Comparative | Surface-modified silica 7 | 24.0 | 41.1 | 7.1 | Ammonium sulfate | 2.8 | 8.8 | 375.8 | [symbol] | [symbol] |
| Example 3 | | | | | | | | | | |
| Comparative | Surface-modified silica 8 | 24.0 | 41.1 | 8.9 | Ammonium sulfate | 2.7 | 8.7 | [symbol] | 421.4 | [symbol] |
| Example 4 | | | | | | | | | | |
| Comparative | Surface-modified silica 9 | 24.0 | 41.1 | 10.7 | Ammonium sulfate | 2.7 | 8.7 | 238.7 | 418.7 | [symbol] |
| Example 5 | | | | | | | | | | |
| Comparative | Surface-modified silica 10 | 24.0 | 41.1 | 14.3 | Ammonium sulfate | 2.7 | 8.8 | 228.1 | 430.5 | [symbol] |
| Example 6 | | | | | | | | | | |
| Example 7 | Surface-modified silica 4 | 24.0 | 41.1 | 1.8 | — | 2.9 | 1.4 | [symbol] | 218.9 | 2.1 |
| Example 8 | Surface-modified silica 4 | 24.0 | 41.1 | 1.8 | Ammonium sulfate | 1.5 | 21.1 | 519.9 | [symbol] | 1.2 |
| Example 9 | Surface-modified silica 4 | 24.0 | 41.1 | 1.8 | Ammonium sulfate | 2.0 | 12.6 | [symbol] | 442.0 | 1.2 |
| Examde 10 | Surface-modified silica 4 | 24.0 | 41.1 | 1.8 | Ammonium sulfate | 4.0 | 8.4 | 502.2 | 401.1 | 1.3 |
| Comparative | Surface-modified silica 4 | 24.0 | 41.1 | 1.8 | Ammonium sulfate | 5.0 | 8.2 | [symbol] | 302.9 | 1.0 |
| Example 7 | | | | | | | | | | |
| Comparative | Surface-modified silica 4 | 24.0 | 41.1 | 1.8 | Ammonium sulfate | 6.0 | 8.1 | [symbol] | [symbol] | 2.4 |
| Example 8 | | | | | | | | | | |
| Comparative | Surface-modified silica 4 | 24.0 | 41.1 | 1.8 | Ammonium sulfate | 7.0 | 8.1 | [symbol] | [symbol] | 3.4 |
| Example 9 | | | | | | | | | | |
| Comparative | Surface-modified silica 11 | 13.8 | 30.8 | [symbol] | Ammonium sulfate | 2.7 | [symbol] | [symbol] | 257.3 | 1.3 |
| Example 10 | | | | | | | | | | |
| Example 11 | Surface-modified silica 12 | 35.0 | [symbol] | 1.7 | Ammonium sulfate | 3.0 | [symbol] | [symbol] | 301.7 | [symbol] |
| Example 12 | Surface-modified silica 13 | 78.3 | 112 | 2.0 | Ammonium sulfate | 2.9 | [symbol] | [symbol] | [symbol] | [symbol] |
| Example 13 | Surface-modified silica 14 | [symbol] | 201.9 | 1.9 | Ammonium sulfate | 3.0 | [symbol] | [symbol] | 222.9 | 2.2 |

[symbol]

indicates data missing or illegible when filed

From the results in Table 2, it was shown that pH of the polishing composition is within a specific range (less than 5.0), the surface coverage of silanol groups present on the surface of silica particles as abrasive grains is within a specific range (more than 0% and 6.0% or less), and the average primary particle diameter of the silica particles is 20 nm or more and 100 nm or less, thereby improving the polishing removal rate of the silicon oxide film. At this time, it was shown that the silicon oxide film and the silicon nitride film can be polished at the substantially same rate.

On the other hand, when pH of the polishing composition was out of the range of the present invention (5.0 or more), the polishing removal rate of the silicon oxide film decreased. When pH was particularly high, the result was obtained in which it was difficult to polish the silicon oxide film and the silicon nitride film at the same rate (Comparative Examples 8 and 9). When the average primary particle diameter of the silica particles as abrasive grains was less than 20 nm, the silicon oxide film and the silicon nitride film could be polished at the same rate, but the polishing removal rate of the silicon oxide film was not sufficiently obtained (Comparative Example 10).

It was shown that the polishing composition containing an ammonium salt as an additive improves the polishing removal rate of the silicon oxide film (Comparison between Example 4 and Example 7).

The present application is based on Japanese Patent Application No. 2022-053013 filed on Mar. 29, 2022, the disclosure content of which is incorporated herein by reference in its entirety.

1. A polishing composition comprising abrasive grains and a dispersing medium,
wherein pH is less than 5.0,
the abrasive grains are surface-modified silica particles in which an organic acid is immobilized on a surface thereof,
a surface coverage of silanol groups present on a surface of the surface-modified silica particles is more than 0% and 6.0% or less, and
an average primary particle diameter of the abrasive grains is 20 nm or more and 100 nm or less.

2. The polishing composition according to claim 1, wherein the surface coverage is 0.050% or more and 5.0% or less.

3. The polishing composition according to claim 2, wherein the surface coverage is 0.50% or more and less than 3.6%.

4. The polishing composition according to claim 1, wherein pH is 1.5 or more and less than 4.0.

5. The polishing composition according to claim 1, further comprising an ammonium salt.

6. The polishing composition according to claim 5, wherein the ammonium salt comprises at least one selected from the group consisting of ammonium sulfate, ammonium nitrate, diammonium hydrogen citrate, and triammonium citrate.

7. The polishing composition according to claim 1, wherein an average secondary particle diameter of the abrasive grains is 35 nm or more and 250 nm or less.

8. The polishing composition according to claim 1, wherein the average primary particle diameter of the abrasive grains is 50 nm or less.

9. The polishing composition according to claim 1, wherein the abrasive grains are sulfonic acid-modified silica particles in which a sulfonic acid group is immobilized on a surface thereof.

10. The polishing composition according to claim 1, which is used for polishing an object to be polished containing silicon oxide and silicon nitride.

11. A polishing method comprising polishing an object to be polished containing silicon oxide and silicon nitride by using the polishing composition according to claim 1.
